(19) United States
(12) Patent Application Publication
(10) Pub. No.: US 2026/0123322 A1
(43) Pub. Date: Apr. 30, 2026

(54) FABRICATION PROCESS FOR DICING INTEGRATED CIRCUIT (IC) DIES

(71) Applicant: TEXAS INSTRUMENTS INCORPORATED, DALLAS, TX (US)

(72) Inventors: MICHAEL TODD WYANT, DALLAS, TX (US); ANINDYA PODDAR, SUNNVALE, CA (US); KASHYAP MOHAN, IRVING, TX (US)

(21) Appl. No.: 18/934,001

(22) Filed: Oct. 31, 2024

(51) Int. Cl. H01L 21/78; H01L 21/3065; H01L 21/683

(52) U.S. Cl. CPC H10P 54/00; H10P 50/242; H10P 72/7402; H10P 72/7416

(57) ABSTRACT

One example includes a method for dicing a semiconductor wafer that includes a plurality of integrated circuit (IC) dies. The method includes providing a plasma-etch through a portion of thickness of a substrate of the semiconductor wafer between fabricated circuits of the semiconductor wafer to provide an etched semiconductor wafer. The method also includes providing a pliable material on the fabricated circuits. The method also includes back-grinding the etched semiconductor wafer to separate the IC dies to provide separated IC dies. Each of the separated IC dies can include a respective one of the fabricated circuits. The method further includes providing the separated IC dies on a die-attach film (DAF), and removing the pliable material.

### TECHNICAL FIELD

This description relates generally to integrated circuit fabrication systems, and more particularly to a fabrication process for dicing integrated circuit dies.

### BACKGROUND

Integrated circuit (IC) packages have long been implemented in computer devices for providing increasingly compact circuits in computer products. Some ICs can be formed as flip-chip devices and/or quad flat no-lead (QFN) packages that may include conductive posts that form electrical contact to associated contact pads on a printed circuit board (PCB). Fabrication of integrated circuits typically includes etching of semiconductor material in any of a variety of ways. One such example of etching is plasma-etching. Plasma etching can be implemented to provide dicing of IC dies by providing an etch between each of the IC dies on a semiconductor wafer.

### SUMMARY

One example includes a method for dicing a semiconductor wafer that includes a plurality of integrated circuit (IC) dies. The method includes providing a plasma-etch through a portion of thickness of a substrate of the semiconductor wafer between fabricated circuits of the semiconductor wafer to provide an etched semiconductor wafer. The method also includes providing a pliable material on the fabricated circuits. The method also includes back-grinding the etched semiconductor wafer to separate the IC dies to provide separated IC dies. Each of the separated IC dies can include a respective one of the fabricated circuits. The method further includes providing the separated IC dies on a die-attach film (DAF), and removing the pliable material.

Another example includes an IC dicing system. The system includes a plasma-etching tool configured to provide a first plasma-etch through a portion of thickness of a semiconductor wafer between fabricated circuits of the semiconductor wafer to provide an etched semiconductor wafer. The system also includes a back-grinding tool configured to back-grind the etched semiconductor wafer to separate the IC dies to provide separated IC dies. Each of the separated IC dies can include a respective one of the fabricated circuits. The system further includes wafer-handling equipment configured to adhere the separated IC dies onto the DAF that is arranged between the separated IC dies and a dicing tape. The plasma-etching tool can be further configured to provide a second plasma-etch through the DAF between the separated IC dies.

Another example described herein includes a method for dicing a semiconductor wafer that includes a plurality of IC dies. The method includes providing a first plasma-etch through a portion of thickness of a substrate of the semiconductor wafer between fabricated circuits of the semiconductor wafer to provide an etched semiconductor wafer. The method also includes back-grinding the etched semiconductor wafer to separate the IC dies to provide separated IC dies. Each of the separated IC dies can include a respective one of the fabricated circuits. The method also includes providing the separated IC dies on a DAF that is arranged between the separated IC dies and a dicing tape. The method further includes providing a second plasma-etch on the separated IC dies to etch through the DAF between each of the separated IC dies, and stretching the dicing tape to singulate the separated IC dies.

Another example described herein includes an IC device. The device includes an IC die comprising a fabricated circuit formed on a substrate. The fabricated circuit can include an oxide material layer on an exposed surface of the fabricated circuit. The oxide material layer can exhibit degradation caused by plasma-etching. The device further includes a package that substantially surrounds the IC die.

### BRIEF DESCRIPTION OF THE DRAWINGS

FIG. 1 is an example block diagram of an integrated circuit (IC) dicing system.

FIG. 2 is an example of a semiconductor wafer.

FIG. 3 is an example of a first fabrication step of dicing a semiconductor wafer.

FIG. 4 is an example of a second fabrication step of dicing the semiconductor wafer.

FIG. 5 is an example of a third fabrication step of dicing the semiconductor wafer.

FIG. 6 is an example of a fourth fabrication step of dicing the semiconductor wafer.

FIG. 7 is an example of a fifth fabrication step of dicing the semiconductor wafer.

FIG. 8 is an example of a sixth fabrication step of dicing the semiconductor wafer.

FIG. 9 is an example of a seventh fabrication step of dicing the semiconductor wafer.

FIG. 10 is an example of an eighth fabrication step of dicing the semiconductor wafer.

FIG. 11 is an example of a ninth fabrication step of dicing the semiconductor wafer.

FIG. 12 is an example of a tenth fabrication step of dicing the semiconductor wafer.

FIG. 13 is an example of an eleventh fabrication step of dicing the semiconductor wafer.

FIG. 14 is an example of a twelfth fabrication step of dicing the semiconductor wafer.

FIG. 15 is an example of an IC device.

FIG. 16 is an example a method for dicing a semiconductor wafer.

FIG. 17 is another example a method for dicing a semiconductor wafer.

### DETAILED DESCRIPTION

This description relates generally to integrated circuit fabrication systems, and more particularly to a fabrication process for dicing integrated circuit dies. Fabrication processes typically include fabricating circuit devices on a semiconductor wafer via any of a variety of integrated circuit (IC) fabrication processes. Such processes typically involve dicing IC dies, which refers to separating the IC dies from each other out of the semiconductor wafer. Dicing can be implemented in any of a variety of ways, including etching processes that can be implemented similar to etching during fabrication of the circuit devices therein. To implement an etch for dicing, the semiconductor material that forms the semiconductor wafer is typically ground-down in back-grinding process to remove a significant thickness of the semiconductor material.

Conventional fabrication processes can include back-grinding the semiconductor wafer. The back-grinding process typically involves providing a back-grinding tape over the fabricated circuits (e.g., on a surface opposite the back-grinded surface) to handle the semiconductor wafer for the back-grinding process. However, the etching process typically requires a photoresist layer to be provided over the fabricated circuits to facilitate etching the semiconductor wafer without damaging the fabricated circuits. Therefore, the back-grinding tape can be applied after the deposition of the photoresist, and thus after the photoresist is deposited on the fabricated circuits.

After the back-grinding in a conventional fabrication process, the thinned semiconductor wafer can be adhered to a dicing tape and/or a die-attach film (DAF), such as for quad-flat no lead (QFN) packages. Upon adhering the thinned semiconductor wafer, the thinned semiconductor wafer can subsequently be etched (e.g., plasma-etched) to dice the fabricated circuits to provide separated IC dies in the example conventional fabrication process. However, in such a conventional process, the etching (e.g., plasma-etching) to dice the fabricated circuits can result in damage to components necessary for the fabrication process.

As one example, by etching the back-grinded semiconductor wafer after the semiconductor wafer has been adhered to the dicing tape can result in damage to the dicing tape, such as to result in breakage with the dicing tape is stretched for singulation of the IC dies. As another example, to adhere the semiconductor wafer to a DAF (e.g., on a 2:1 tape that includes a DAF and a dicing tape), the fabrication process can include heating the environment to allow the adherence of the DAF to the semiconductor wafer. However, as described above, the semiconductor wafer can have a photoresist deposited over the fabricated circuits and under the back-grinding tape during this process. The heat resulting from adherence of the semiconductor wafer to the DAF can cause bubbles to form in the photoresist, thus resulting in potential damage to the fabricated circuits during a subsequent dicing etch (e.g., a plasma-etch).

To mitigate breakage of the dicing tape and/or damage the fabricated circuits, the fabrication process described herein can implement a dice-before-grind (DBG) operation in which the semiconductor wafer is plasma-etched before the back-grinding of the semiconductor wafer. In the fabrication process described herein, the photoresist is removed after the plasma-etching of the semiconductor wafer to dice the semiconductor wafer into separated IC dies via the back-grinding of the etched semiconductor wafer. The separated IC dies are then adhered to a DAF in a heated environment. The absence of the photoresist in the adherence to DAF step thus mitigates damage to the fabricated circuits due to the absence of the photoresist that can form bubbles.

Additionally, because the separated IC dies are adhered to the DAF and dicing tape (e.g., 2:1 tape) after the plasma-etch, damage from the plasma-etching of the semiconductor wafer can be prevented from the plasma-etch of the semiconductor wafer. The fabrication process described herein can also implement a second plasma-etch to etch through the DAF for singulation of the separated IC dies. The fabrication process can thus implement a cover plate that covers the wafer exclusion zone of the DAF and dicing tape to mitigate damage to the dicing tape. Accordingly, damage to the dicing tape that can result in breakage from stretching is mitigated, as well.

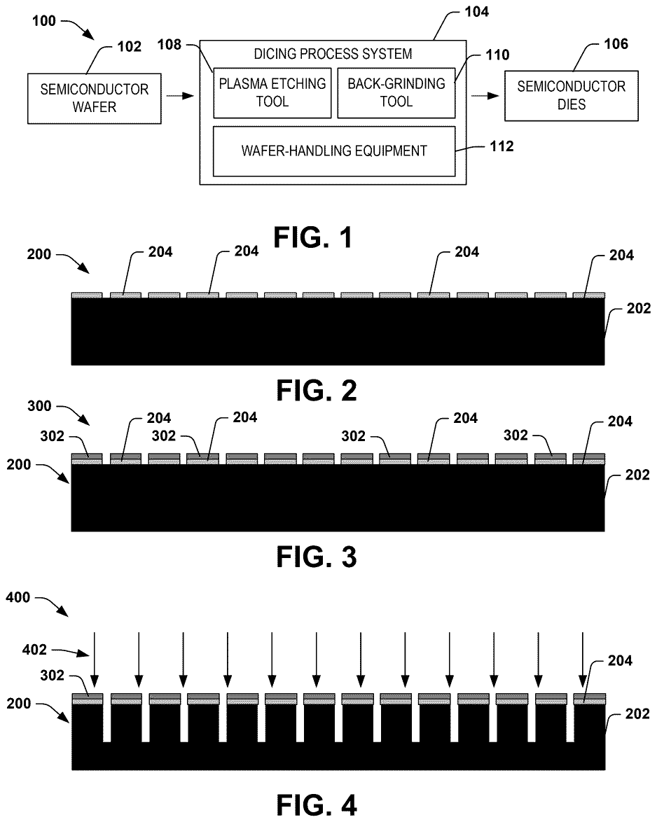

FIG. 1 is an example block diagram of an integrated circuit (IC) dicing system 100. The IC dicing system 100 can be implemented in any of a variety of fabrication applications, such as subsequent to fabrication of integrated circuits on a semiconductor wafer, demonstrated at 102. The semiconductor wafer 102 can include a semiconductor (e.g., silicon) substrate on which circuits can be fabricated on one or more layers over the substrate.

As described in greater detail herein, the fabricated circuits can include one or more oxide layers over and/or within the fabricated circuit layer(s). The IC dicing system 100 can be a portion of an entire fabrication system for fabricating IC devices, and particularly provides dicing of the semiconductor wafer to provide individually separated IC dies. As described herein, the terms “fabrication process” and “dicing process” refer to the portion of the entire fabrication process that is provided by the IC dicing system 100, and are used interchangeably herein.

In the example of FIG. 1, the semiconductor wafer 102 is provided to a dicing process system 104. The dicing process system 104 can be implemented to dice and singulate the fabricated circuits on the semiconductor wafer 102 into a plurality of IC dies 106. The singulated IC dies 106 can then be packaged as IC chips for consumer distribution. As an example, the packaging of the IC chips can include attaching the IC dies to a lead-frame (e.g., via a die-attach film (DAF)), providing the IC dies in respective packages, and filling the packages with a molding material.

The dicing process system 104 includes a plasma-etching tool 108, a back-grinding tool 110, and wafer-handling equipment 112. The wafer-handling equipment 112 can refer to any of a variety of machinery, equipment, and devices that can move, handle, and/or manipulate the semiconductor wafer 102. As described herein, the plasma-etching tool 108 can be configured to implement a first plasma-etch and a second plasma-etch at different stages of the dicing process. The back-grinding tool 110 is configured to implement back-grinding of the semiconductor wafer 102. As described herein, the first plasma-etch can be provided by the plasma-etching tool 108 before the back-grinding provided by the back-grinding tool 110. In this manner, the fabrication process described herein implements a dice-before-grinding (DBG) procedure.

In the DBG fabrication process described herein, a photoresist is provided on the fabricated circuits of the semiconductor wafer 102 before implementing the first plasma-etch via the plasma-etching tool 108 to dice the fabricated circuits. The first plasma-etch can be provided through a portion (less than all) of the thickness of the semiconductor wafer 102. The photoresist can then be removed, and the back-grinding tool 110 can subsequently implement a back-grinding process of the etched semiconductor wafer to provide separated IC dies that each include one of the fabricated circuits on a substrate. The separated IC dies are then adhered to a DAF via a heat application procedure (e.g., via the wafer-handling equipment 112). Therefore, because the photoresist is removed after the plasma-etching of the semiconductor wafer and before the adherence of the separated IC dies to the DAF, the formation of bubbles on photoresist prior to etching can be prevented in the dicing process described herein.

Additionally, as described in greater detail herein, damage to the dicing tape resulting from the plasma-etch can be mitigated, as well. For example, the fabrication process described herein can also implement a second plasma-etch via the plasma-etching tool 108 to etch through the DAF for singulation of the separated IC dies. The fabrication process can thus implement a cover plate that covers the wafer exclusion zone of the DAF and dicing tape to mitigate damage to the dicing tape. Accordingly, damage to the dicing tape that can result in breakage from stretching is mitigated as well.

FIG. 2 is an example diagram of a semiconductor wafer 200. The semiconductor wafer 200 can correspond to the semiconductor wafer 102 in the example of FIG. 1, and can thus be provided to the dicing process system 104. The semiconductor wafer 200 can be implemented to fabricate any of a variety of IC circuit devices (e.g., in a quad flat no-lead (QFN) package). The semiconductor wafer 200 is demonstrated in the example of FIG. 2 in a cross-sectional view to show the relative locations of layers. The semiconductor wafer 200 is demonstrated by example, and is not intended to be illustrated to scale.

The semiconductor wafer 200 includes a substrate 202 and a plurality of fabricated circuits 204 that are fabricated on the substrate 202. The fabricated circuits 204 can each correspond to a circuit that can be included in a respective IC device upon completion of the fabrication process. As an example, and as described in greater detail herein, the fabricated circuits 204 can each include one or more layers of an oxide material that is formed on an exposed surface of the fabricated circuits 204.

FIGS. 3-14 demonstrate fabrication steps for dicing the semiconductor wafer 200 in the examples described herein. Therefore, like reference numbers are used in the examples of FIGS. 3-14 as provided in FIG. 2, and reference to FIG. 2 is to be made in the following examples of FIGS. 3-14. The fabrication steps described in the example of FIGS. 3-14 can be implemented, for example, by the dicing process system 104 in the example of FIG. 1.

FIG. 3 is an example of a first fabrication step 300. In the first fabrication step 300, a photoresist layer 302 is formed over each of the fabricated circuit 204. In the example of FIG. 3, the photoresist layer 302 is demonstrated as individual photoresist portions that are formed over each individual fabricated circuit 204, such that an outer periphery of each portion of the photoresist layer 302 can be approximately aligned with the outer periphery of a respective one of the fabricated circuits 204.

FIG. 4 is an example of a second fabrication step 400. In the second fabrication step 400, a first plasma-etch, demonstrated generally at 402, is provided on the semiconductor wafer 200 (e.g., via the plasma-etching tool 108). Particularly, the first plasma-etch 402 is provided on the photoresist layer 302 and on the portions of the substrate 202 between each of the fabricated circuits 204. In the example of FIG. 4, the first plasma-etch 402 is demonstrated as a partial etch through the thickness of the substrate 202, and thus through less than the entire thickness of the substrate 202/semiconductor wafer 200.

The second fabrication step 400 thus demonstrates dicing the fabricated circuits 204, which occurs before the back-grinding implemented by the back-grinding tool 110. Therefore, the fabrication process described herein demonstrates a DBG fabrication technique.

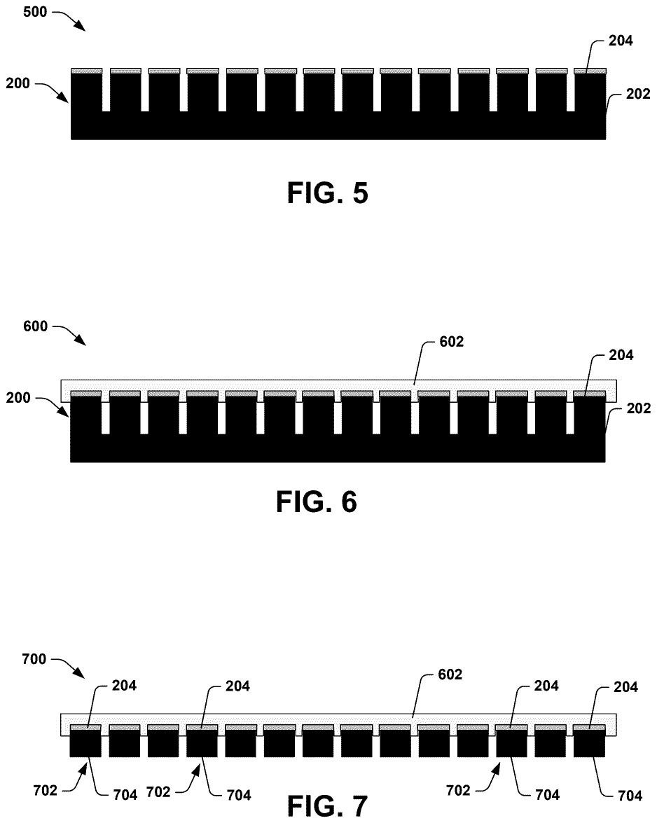

FIG. 5 is an example of a third fabrication step 500. In the third fabrication step 500, the photoresist layer 302 is removed. At this step 500, because the photoresist material of the photoresist layer 302 has been removed, there is no subsequent plasma-etch of the photoresist that can cause damage to the fabricated circuits 204 beneath the photoresist layer 302. In other words, because the removal of the photoresist layer 302 occurs at the third fabrication step 500 before the semiconductor wafer 200 is adhered to a DAF, bubbles cannot form in the photoresist material of the photoresist layer 302 in response to the heated environment that facilitates the adherence of the semiconductor material to the DAF. Therefore, by implementing the DBG fabrication technique in which the first plasma-etch 402 of the second fabrication step 400 occurs prior to the adherence of the semiconductor wafer 200 to the DAF, damage to the fabricated circuits 204 can be mitigated.

FIG. 6 is an example of a fourth fabrication step 600. In the fourth fabrication step 600, a pliable material 602 is provided over the fabricated circuits 204, such as via the wafer-handling equipment 112. The pliable material 602 can correspond to any of a variety of elastically deformable materials that can be disposed over the fabricated circuits 204 and in at least a portion of the depth of the partial etch between the fabricated circuits 204. As another example, the pliable material 602 can be non-adhesive, so as to be completely removable from the semiconductor wafer 200 without leaving residue on the fabricated circuits 204 and/or the substrate material of the substrate 202. Examples of such a pliable material include a back-grinding tape, an edge glue tape (EGT), or any of a variety of similar types of materials.

FIG. 7 is an example of a fifth fabrication step 700. In the fifth fabrication step 700, the semiconductor wafer 200 is back-grinded by the back-grinding tool 110. As an example, the wafer-handling equipment 112 can be configured to handle/secure the semiconductor wafer 200 via the pliable material 602 to allow access of the back-grinding tool 110 to the substrate 202 opposite the pliable material 602 and the fabricated circuits 204. Therefore, the back-grinding tool 110 can back-grind the contiguous portion of the substrate 202 completely to provide separated IC dies 702. The separated IC dies 702 each include one of the fabricated circuits 204 formed over a substrate 704 that corresponds to a remaining portion of the substrate 202. The securing of the semiconductor wafer 200 by the pliable material 602 allows the back-grinding tool 110 to separate the IC dies 702 while maintaining the position of the separated IC dies relative to each other.

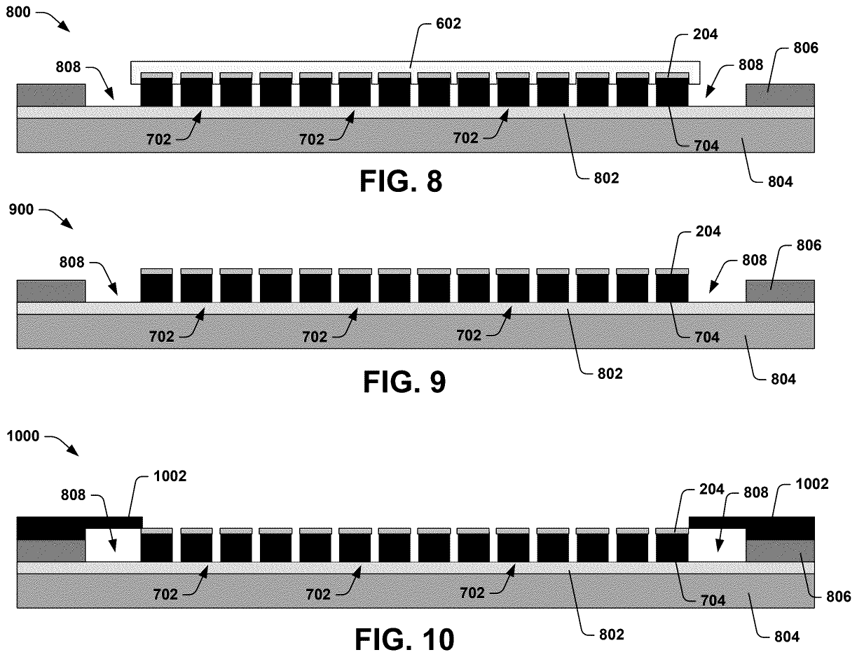

FIG. 8 is an example of a sixth fabrication step 800. In the sixth fabrication step 800, a DAF 802 is adhered to the substrates 704 of the separated IC dies 702. The pliable material 602 is able to facilitate the adherence of the substrates 704 of the separated IC dies 702 to the DAF 802 in a controlled and collective manner. In the example of FIG. 8, the DAF 802 can be provided as part of a 2:1 tape that includes a dicing tape 804 that is coupled to the DAF 802 on a surface of the DAF 802 opposite the substrates 704. However, the DAF 802 and the dicing tape 804 can alternatively be provided separately. In the example of FIG. 8, the DAF 802 and the dicing tape 804 (e.g., the 2:1 tape) are demonstrated as being secured by a ring structure 806 (e.g., a stainless-steel ring that surrounds a periphery of the DAF 802 and the dicing tape 804). The region on the DAF 802 between the ring structure 806 and the separated IC dies 702 at the edges of the array of IC dies 702 can correspond to a wafer-exclusion zone 808 at which the DAF 802 is exposed.

As described above, the adherence of the substrates 704 of the separated IC dies 702 can be provided in a heated environment (e.g., approximately 50° C. to approximately 70° C.). However, because the plasma-etch was completed in the second fabrication step 400, and because the photoresist layer 302 was removed in the third fabrication step 500, there is no possibility of bubbles forming in the photoresist material that could cause deleterious effects to the fabricated circuits 204 during a plasma-etch, as opposed to the possibility in a conventional dicing process.

FIG. 9 is an example of a seventh fabrication step 900. In the seventh fabrication step 900, the pliable material 602 is removed from the separated IC dies 702. As described above, the pliable material 602 can be non-adhesive, so as to be completely removable from the separated IC dies 702 without leaving a residue. Therefore, the separated IC dies 702 can be further processed without difficult and/or expensive chemical cleaning processes to remove the pliable material 602.

FIG. 10 is an example of an eighth fabrication step 1000. In the eighth fabrication step 1000, a cover plate 1002 provided over the wafer-exclusion zone 808. The cover plate 1002 can thus correspond to another ring (with a circular, square, rectangular, or other shaped hole) that covers the ring structure 806 as well as the wafer-exclusion zone 808 while leaving exposed the separated IC dies 702 and the portions of the DAF 802 between the separated IC dies 702.

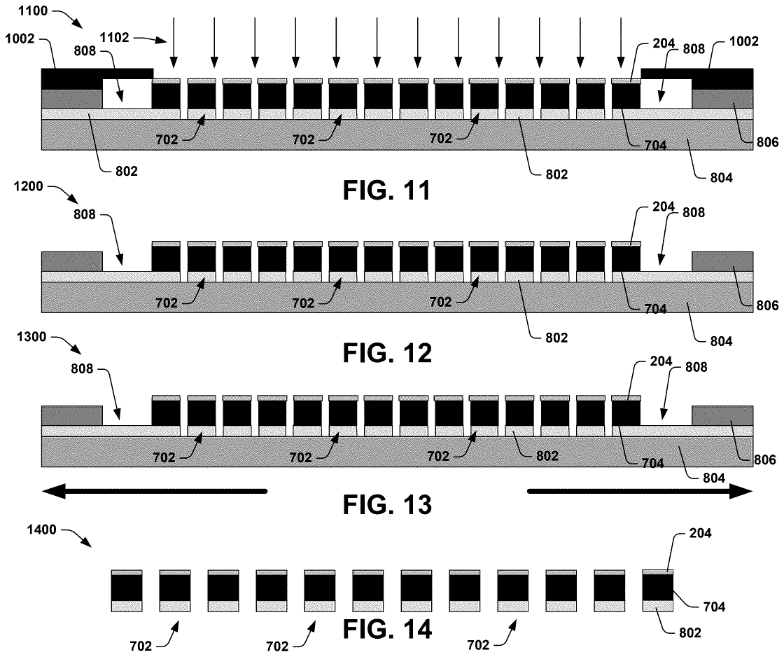

FIG. 11 is an example of a ninth fabrication step 1100. In the ninth fabrication step 1100, a second plasma-etch, demonstrated generally at 1102, is provided on the separated IC dies 702 (e.g., via the plasma-etching tool 108). Particularly, the second plasma-etch 1102 is provided on the fabricated circuits 204 and on the exposed portions of the DAF 802 between the separated IC dies 702. The second plasma-etch 1102 can etch the exposed portions of the DAF 802 between the separated IC dies 702, thereby exposing the dicing tape 804 between the separated IC dies 702.

As described above, the cover plate 1002 covers the wafer-exclusion zone 808 while leaving exposed the separated IC dies 702 and the portions of the DAF 802 between the separated IC dies 702. Therefore, the second plasma-etch 1102 is able to etch the DAF 802 between the separated IC dies 702, the portion of the DAF 802 in the wafer-exclusion zone 808 remain unetched and intact. Therefore, the cover plate 1002 can protect the dicing tape 804 beneath the portion of the DAF 802 in the wafer-exclusion zone 808 from damage. Therefore, when the dicing tape 804 is stretched, breakage of the dicing tape 804 can be mitigated.

Additionally, as described above, the fabricated circuits 204 can each include one or more layers of an oxide material that is formed on an exposed surface of the fabricated circuits 204. The oxide material layer(s) can, for example, be part of a typical fabrication process of the fabricated circuits 204. However, the second plasma-etch 1102 can be provided with a plasma material having chemical properties to which the oxide layer(s) are resistant.

For example, the plasma material may be formed by chemical processes that significantly affect a difference in the etching rates of the etching of the DAF 802 and the oxide layer(s), with the oxide layer(s) being etched significantly more slowly than the DAF 802. Accordingly, the oxide layer(s) can behave as a mask over the fabricated circuits 204 to protect the fabricated circuits 204 from damage resulting from the second plasma-etch 1102 while allowing the exposed portions of the DAF 802 to be substantially completely etched away. As a result, the fabrication process described herein does not require an additional photoresist or mask to be applied over the fabricated circuits 204 to protect the fabricated circuits 204 from the second plasma-etch 1102.

FIG. 12 is an example of a tenth fabrication step 1200. In the tenth fabrication step 1200, the cover plate 1002 is removed. Therefore, the portion of the DAF 802 in the wafer-exclusion zone 808 and the ring structure 806 are again exposed, having been protected from the second plasma-etch 1102 by the cover plate 1002.

FIG. 13 is an example of an eleventh fabrication step 1300. In the eleventh fabrication step 1300, the dicing tape 804 is stretched to increase the spacing between the separated IC dies 702. Therefore, the separated IC dies 702 can be singulated into individual IC dies 702 that can be provided on lead-frames and packaged. As described above, the cover plate 1002 can protect the dicing tape 804 from damage resulting from the second plasma-etch 1102. Therefore, the risk of breaking the dicing tape 804 during the stretching of the dicing tape 804 in the eleventh fabrication step 1300 can be mitigated.

FIG. 14 is an example of a twelfth and last fabrication step 1400. In the twelfth fabrication step 1400, the separated IC dies 702 are removed from the stretched dicing tape 804 and singulated. As an example, because the portion of the DAF 802 in the wafer-exclusion zone 808 was not etched by the second plasma-etch 1102, the separated IC dies 702 at the edges of the array of IC dies 702, and thus next to the wafer-exclusion zone 808, may not be able to be removed from the portion of the DAF 802 in the wafer-exclusion zone 808. Therefore, the separated IC dies 702 at the edges of the array of IC dies 702 may be scrapped based on an inability to singulate the respective IC dies 702. Alternatively, instead of scrapping the separated IC dies 702 at the edges of the array, they could be further processed to remove the associated processing materials. For example, the additional die attach film 802 extending away from the side surface of the IC dies 702 and/or the dicing tape 804 on the remaining die attach film on the bottom surface of the separated IC dies 702 at the edges of the array can be removed for further processing of the associated IC dies 702.

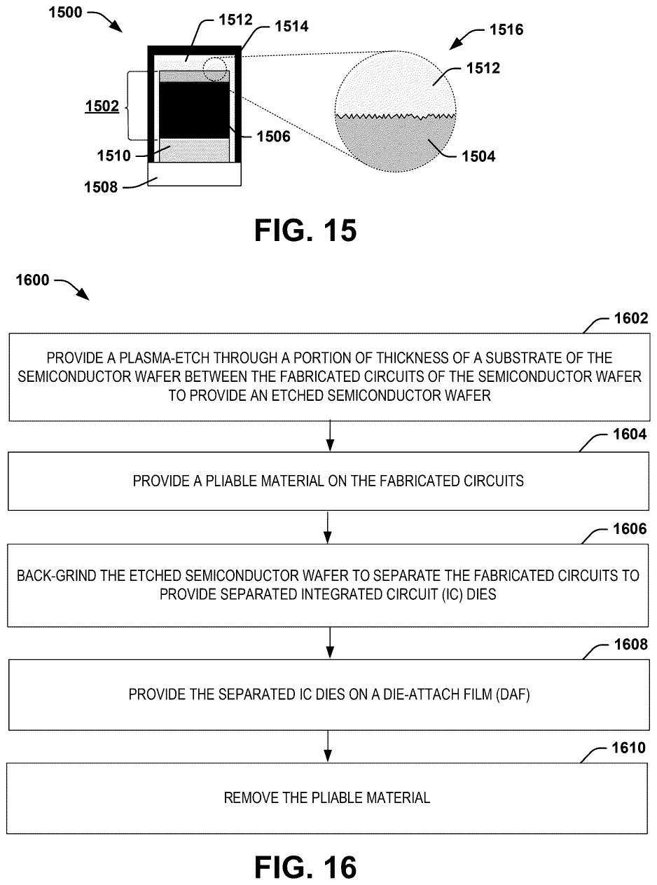

FIG. 15 illustrates an example of an IC device 1500. The IC device 1500 includes an IC die 1502 that can correspond to one of the separated IC dies 702 that is provided from the fabrication process described herein, and thus having been diced from the semiconductor wafer 200. The IC die 1502 thus includes a fabricated circuit 1504 on a substrate 1506. The IC die 1502 is coupled to a lead-frame 1508 via a DAF 1510. As an example, the IC device 1500 can be arranged as a QFN device, such that the lead-frame 1508 includes conductive pads that can be conductively coupled to contacts of a printed circuit board (PCB). The IC die 1502 (e.g., and the DAF 1510) can be surrounded by a package that includes a molding material 1512 having an outer surface 1514. Alternatively, outer surface 1514 could be formed by a plastic exterior jacket for the IC device 1500, in which case the molding material 1512 is filled within the interior volume of the plastic exterior jacket 1514.

As described above, the fabricated circuit 1504 can include one or more layers of an oxide material that is formed on an exposed surface of the fabricated circuit 1504. As also described above, the plasma material implemented for the second plasma-etch 1102 can have chemical properties to which the oxide layer(s) are resistant. Thus, the fabricated circuit 1504 can be protected from the second plasma-etch 1102 by the oxide material layer(s). However, the oxide layer(s) on the fabricated circuit 1504 can exhibit an indication of the occurrence of the second plasma-etch 1102 based on identifiable degradation of the oxide material.

In the example of FIG. 15, the surface of the oxide layer(s) (not shown) on the fabricated circuit 1504 can exhibit the signs of having been plasma-etched, as demonstrated in the magnified section 1516 of the fabricated circuit 1504. The surface of the oxide layer(s) on the fabricated circuit 1504 is demonstrated as having a rough surface (by example), though the surface can instead exhibit any of a variety of other indications of degradation resulting from the plasma-etching process. Such an indication of the plasma-etching of the oxide layer(s) of the fabricated circuit 1504 (e.g., based on scanning electron microscope SEM inspection) can provide an indication that the IC device 1500 was diced based on the fabrication process described herein.

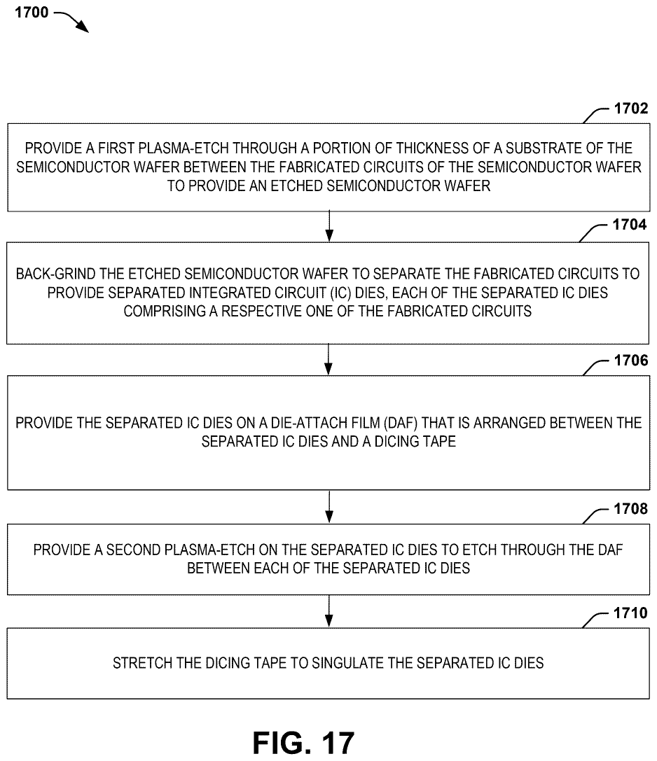

In view of the foregoing structural and functional features described above, a methodology in accordance with various aspects of the present invention will be better appreciated with reference to FIGS. 16 and 17. While, for purposes of simplicity of explanation, the methodology of FIGS. 16 and 17 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 16 illustrates another example of a method 1600 for dicing a semiconductor wafer (e.g., the semiconductor wafer 102) comprising a plurality of fabricated circuits (e.g., the fabricated circuits 204). At 1602, a plasma-etch (e.g., the first plasma-etch 402) is provided through a portion of thickness of a substrate (e.g., the substrate 202) of the semiconductor wafer between the fabricated circuits of the semiconductor wafer to provide an etched semiconductor wafer. At 1604, a pliable material (e.g., the pliable material 602) is provided on the fabricated circuits. At 1606, the etched semiconductor wafer is back-grinded to separate the fabricated circuits to provide separated IC dies (e.g., the separated IC dies 702). Each of the separated IC dies can include a respective one of the fabricated circuits. At 1608, the separated IC dies are provided on a DAF (e.g., the DAF 802). At 1610, the pliable material is removed.

FIG. 17 illustrates an example of a method 1700 dicing a semiconductor wafer (e.g., the semiconductor wafer 102) comprising a plurality of fabricated circuits (e.g., the fabricated circuits 204). At, 1702, a first plasma-etch (e.g., the first plasma-etch 402) is provided through a portion of thickness of a substrate (e.g., the substrate 202) of the semiconductor wafer between the fabricated circuits of the semiconductor wafer to provide an etched semiconductor wafer. At 1704, the etched semiconductor wafer is back-grinded to separate the fabricated circuits to provide separated IC dies (e.g., the separated IC dies 702). Each of the separated IC dies can include a respective one of the fabricated circuits. At 1706, the separated IC dies are provided on a (e.g., the DAF 802) that is arranged between the separated IC dies and a dicing tape (e.g., the dicing tape 804). At 1708, a second plasma-etch (e.g., the second plasma-etch 1102) is provided on the separated IC dies to etch through the DAF between each of the separated IC dies. At 1710, the dicing tape is stretched to singulate the separated IC dies.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A method for dicing a semiconductor wafer comprising a plurality of fabricated circuits, the method comprising:
providing a plasma-etch through a portion of thickness of a substrate of the semiconductor wafer between the fabricated circuits of the semiconductor wafer to provide an etched semiconductor wafer;
providing a pliable material on the fabricated circuits;
back-grinding the etched semiconductor wafer to separate the fabricated circuits to provide separated integrated circuit (IC) dies, each of the separated IC dies comprising a respective one of the fabricated circuits;
providing the separated IC dies on a die-attach film (DAF); and
removing the pliable material.

2. The method of claim 1, wherein providing the plasma-etch comprises:
forming a photoresist layer over each of the fabricated circuits;
providing the plasma-etch to remove semiconductor material of the substrate of the semiconductor wafer between each of the fabricated circuits to a depth that is less than an entirety of a thickness of the substrate; and
removing the photoresist layer.

3. The method of claim 1, wherein providing the separated IC dies on the DAF comprises coupling the separated IC dies on the DAF to a first surface of the separated IC dies that is opposite a second surface of the separated IC dies to which the pliable material is provided.

4. The method of claim 3, wherein providing the separated IC dies on the DAF further comprises providing the separated IC dies on the DAF arranged between the first surface of the separated IC dies and a dicing tape.

5. The method of claim 1, wherein the plasma-etch is a first plasma-etch, the method further comprising providing a second plasma-etch on the separated IC dies after removing the pliable material to etch through the DAF between each of the separated IC dies.

6. The method of claim 5, wherein the fabricated circuits are fabricated with an oxide material over the fabricated circuits of the semiconductor wafer, wherein providing the second plasma-etch comprises providing a plasma material of the second plasma-etch over the fabricated circuits and over the DAF between each of the separated IC dies.

7. The method of claim 5, wherein providing the second plasma-etch on the separated IC dies comprises:
providing a cover plate over a wafer exclusion zone corresponding to a periphery of the DAF that at least partially surrounds the separated IC dies; and
providing the second plasma-etch on the separated IC dies and on the cover plate to protect the DAF in the wafer exclusion zone.

8. The method of claim 7, wherein the DAF is provided on a dicing tape, the method further comprising:
removing the cover plate; and
stretching the dicing tape to singulate the separated IC dies.

9. An integrated circuit (IC) dicing system comprising:
a plasma-etching tool configured to provide a first plasma-etch through a portion of thickness of a substrate of a semiconductor wafer between fabricated circuits of the semiconductor wafer to provide an etched semiconductor wafer;
a back-grinding tool configured to back-grind the etched semiconductor wafer to separate the fabricated circuits to provide separated IC dies, each of the separated IC dies comprising a respective one of the fabricated circuits; and
wafer-handling equipment configured to adhere the separated IC dies onto the die-attach film (DAF) that is arranged between the separated IC dies and a dicing tape, the plasma-etching tool being further configured to provide a second plasma-etch through the DAF between the separated IC dies.

10. The system of claim 9, wherein the wafer-handling equipment is further configured to form a photoresist layer over each of the fabricated circuits, such that the plasma-etching tool provides the first plasma-etch over the photoresist layer and exposed portions of the semiconductor wafer between the fabricated circuits of the semiconductor wafer, and further configured to remove the photoresist layer after the first plasma-etch.

11. The system of claim 9, wherein the wafer-handling equipment is further configured to stretch the dicing tape after the second plasma-etch to singulate the separated IC dies.

12. The system of claim 9, wherein the wafer-handling equipment is further configured to provide a pliable material on the fabricated circuits to secure the fabricated circuits, wherein the back-grinding tool is configured to back-grind the etched semiconductor wafer to separate the IC dies to provide the separated IC dies while the fabricated circuits are secured by the pliable material.

13. The system of claim 12, wherein the wafer-handling equipment is further configured to adhere the separated IC dies on the DAF to a first surface of the separated IC dies that is opposite a second surface of the separated IC dies to which the pliable material is applied.

14. The system of claim 9, wherein the fabricated circuits are fabricated with an oxide material over the fabricated circuits of the semiconductor wafer, wherein the plasma-etching tool is configured to provide the second plasma-etch over the fabricated circuits and over the DAF between each of the separated IC dies.

15. The system of claim 9, wherein the wafer-handling equipment is configured to provide a cover plate over a wafer exclusion zone corresponding to a periphery of the DAF that at least partially surrounds the separated IC dies, wherein the plasma-etching tool is configured to provide the second plasma-etch on the separated IC dies and on the cover plate to protect the DAF in the wafer exclusion zone.

16. A method for dicing a semiconductor wafer comprising a plurality of fabricated circuits, the method comprising:
providing a first plasma-etch through a portion of thickness of a substrate of the semiconductor wafer between the fabricated circuits of the semiconductor wafer to provide an etched semiconductor wafer;
back-grinding the etched semiconductor wafer to separate the fabricated circuits to provide separated integrated circuit (IC) dies, each of the separated IC dies comprising a respective one of the fabricated circuits;
providing the separated IC dies on a die-attach film (DAF) that is arranged between the separated IC dies and a dicing tape;
providing a second plasma-etch on the separated IC dies to etch through the DAF between each of the separated IC dies; and
stretching the dicing tape to singulate the separated IC dies.

17. The method of claim 16, wherein providing the first plasma-etch comprises:
forming a photoresist layer over each of the fabricated circuits;
providing the first plasma-etch to remove semiconductor material of the semiconductor wafer between each of the fabricated circuits to a depth that is less than a thickness of the semiconductor wafer; and
removing the photoresist layer.

18. The method of claim 16, further comprising providing a pliable material on the fabricated circuits before back-griding the etched semiconductor wafer, wherein providing the separated IC dies on the DAF comprises coupling the separated IC dies on the DAF to a first surface of the separated IC dies that is opposite a second surface of the separated IC dies to which the pliable material is provided, wherein providing the separated IC dies on the DAF further comprises providing the separated IC dies on the DAF arranged between the first surface of the separated IC dies and the dicing tape.

19. The method of claim 16, wherein the fabricated circuits are fabricated with an oxide material over the fabricated circuits of the semiconductor wafer, wherein providing the second plasma-etch comprises providing a plasma material of the second plasma-etch over the fabricated circuits and over the DAF between each of the separated IC dies.

20. The method of claim 16, wherein providing the second plasma-etch on the separated IC dies comprises:
providing a cover plate over a wafer exclusion zone corresponding to a periphery of the DAF that at least partially surrounds the separated IC dies; and
providing the second plasma-etch on the separated IC dies and on the cover plate to protect the DAF in the wafer exclusion zone.

21. An integrated circuit (IC) device comprising:
an IC die comprising a fabricated circuit formed on a substrate, the fabricated circuit comprising an oxide material layer on an exposed surface of the fabricated circuit, the oxide material layer exhibiting degradation caused by plasma-etching; and
a package that substantially surrounds the IC die.

22. The IC device of claim 21, further comprising:
a die-attach film (DAF) coupled to a first surface of the substrate opposite a second surface on which the fabricated circuit is formed; and
a lead-frame coupled to the DAF.
